(19) United States
(12) Patent Application Publication
(10) Pub. No.: US 2007/0252223 A1
(43) Pub. Date: Nov. 1, 2007

(54) Insulated gate devices and method of making same

(75) Inventors: Minjoo Larry Lee, Cambridge, MA (US); Eugene A. Fitzgerald, Windham, NH (US)

Correspondence Address: WOLF GREENFIELD & SACKS, P.C., 600 ATLANTIC AVENUE, BOSTON, MA, 02210-2206, US

(73) Assignee: Massachusetts Institute of Technology, Cambridge, MA (US)

(21) Appl. No.: 11/634,430

(22) Filed: Dec. 5, 2006

Related U.S. Application Data
(60) Provisional application No. 60/742,490, filed on Dec. 5, 2005.

(51) Int. Cl. H01L 29/78; H01L 21/336

(52) U.S. Cl. 257/411; 438/287; 257/E21.409; 257/E29.255

(57) ABSTRACT

Structures and devices, and methods of making such structures and devices, including a gate dielectric layer are provided. A semiconductor structure can include a semiconductor channel layer including a nitride-free semiconductor layer and a gate dielectric layer including a group III-nitride layer, wherein the gate dielectric layer is disposed over the semiconductor channel layer. A method of making a semiconductor device structure is also provided. The method includes providing a semiconductor channel layer including a nitride-free semiconductor layer and providing a gate dielectric layer including a group III-nitride layer, wherein the gate dielectric layer is disposed over the semiconductor channel layer. A metal-insulator-semiconductor field effect transistor (MISFIT) device structure can include a semiconductor channel layer including a nitride-free semiconductor layer and a gate dielectric layer comprising a group III-nitride layer, wherein the gate dielectric layer is disposed over the semiconductor channel layer. The MISFIT may include a gate electrode disposed over the gate dielectric. The MISFIT may include a source and drain region separated by the semiconductor channel layer.

### RELATED APPLICATIONS

This application claims priority under 35 U.S.C. §119(e) to U.S. Provisional Application Ser. No. 60/742,490, entitled “Structure and Method for an Insulating Gate Device,” filed on Dec. 5, 2005, which is herein incorporated by reference in its entirety.

### FEDERALLY SPONSORED RESEARCH

This invention was made with Government support under Army Research Office grant OSP Project No. 6897688. The Government may have certain rights to this invention.

### FIELD OF INVENTION

The invention relates generally to semiconductor-based electronic devices, and, more particularly, to the structure and fabrication of semiconductor-based electronic devices that include gate dielectric layers.

### BACKGROUND

Complementary metal-oxide-semiconductor (CMOS) technology based on silicon (Si) MOS field-effect transistors (MOSFETs) finds utility in a wide range of large-scale integrated (LSI) circuit applications due in part to its low off-state power consumption. In addition, device scaling has allowed decades of continuous improvements in both the cost-per-function and speed of CMOS circuits. However, the relatively low carrier mobility of Si is an intrinsic material property that can limit the speed and performance of Si MOSFETs.

The use of different semiconductor materials with higher mobility can enable significant increases in MOSFET performance. Germanium (Ge), for example, possesses, an electron mobility (μₑ) of 3900 cm²/Vs and a hole mobility (μₕ) of about 1800 cm²/Vs. Similarly, gallium arsenide (GaAs) possesses a higher bandgap, electron mobility (8500 cm²/Vs), and breakdown field than Si, and the addition of aluminum (Al) and indium (In) can enable the engineering of band offsets and strain.

### SUMMARY

Structures and devices including a gate dielectric layer are provided. Methods of making such structures and devices are also provided.

In one aspect, a semiconductor structure comprises a semiconductor channel layer comprising a nitride-free semiconductor layer and a gate dielectric layer comprising a group III-nitride layer, wherein the gate dielectric layer is disposed over the semiconductor channel layer.

In another aspect, a method of making a semiconductor structure is provided. The method comprises providing a semiconductor channel layer comprising a nitride-free semiconductor layer and providing a gate dielectric layer comprising a group III-nitride layer, wherein the gate dielectric layer is disposed over the semiconductor channel layer.

In another aspect, a metal-insulator-semiconductor field effect transistor (MISFIT) device structure comprises a semiconductor channel layer comprising a nitride-free semiconductor layer, a gate dielectric layer comprising a group III-nitride layer, wherein the gate dielectric layer is disposed over the semiconductor channel layer, a gate electrode disposed over the gate dielectric, and a source region and a drain region separated by the semiconductor channel layer.

### BRIEF DESCRIPTION OF DRAWINGS

The accompanying drawings are not intended to be drawn to scale. In the drawings, each identical or nearly identical component that is illustrated in various figures is represented by a like numeral. For purposes of clarity, not every component may be labeled in every drawing. In the drawings:

FIG. 1 is a schematic of a semiconductor structure including a gate dielectric layer disposed over a semiconductor channel layer in accordance with one embodiment;

FIG. 2 is a schematic of a semiconductor structure including a gate dielectric layer comprising a high-K dielectric layer disposed over a group III-nitride layer in accordance with one embodiment;

FIG. 3 is a schematic of a semiconductor structure including a gate dielectric comprising a group III-nitride layer disposed over a nitride compound of a nitride-free semiconductor in accordance with one embodiment;

FIG. 4 is schematic of a semiconductor structure including a gate dielectric comprising a high-K dielectric layer, a group III-nitride layer, and a nitride compound of a nitride-free semiconductor in accordance with one embodiment;

FIG. 5 is schematic of a metal-insulator-semiconductor field effect transistor (MISFET) device including a gate dielectric layer in accordance with one embodiment;

FIG. 6 is a flowchart of a method of forming a structure including a gate dielectric using deposition process(es) in accordance with one embodiment;

FIG. 7 is a cross-sectional transmission electron microscopy (TEM) image of a group III-nitride gate dielectric deposited over a p-type GaAs starting wafer in accordance with one embodiment;

FIG. 8 is a chart of measured high-frequency capacitance-voltage (HFCV) characteristics for Al/AlN/n-Si capacitors in accordance with one embodiment;

FIG. 9 is a chart of measured HFCV characteristics for Al/AlN/n-Ge capacitors in accordance with one embodiment; and

FIG. 10 is a chart of measured HFCV characteristics for Al/AlN/p-GaAs capacitors in accordance with one embodiment.

### DETAILED DESCRIPTION

Despite the intrinsic materials advantages of non-silicon materials like Ge, GaAs, and other III-V semiconductors, there currently exist no MOSFET technologies based on either Ge, GaAs, or any III-V semiconductor, due in large part to the poor electrical and chemical stability of oxides and other insulators on their surfaces. Many of these oxide/semiconductor interfaces have an extremely high density of traps, which may contribute to Fermi-level pinning. Pinned interfaces are an intractable technical roadblock, since MOS operation relies critically on the ability to control the Fermi-level of the surface.

The poor quality of oxides (e.g., native or deposited oxides) on semiconductor surfaces other than Si (including silicon-germanium (SiGe) alloys, pure Ge, and III-V compounds) has been thoroughly demonstrated. For example, aluminum oxide (Al₂O₃) on GaAs has previously been shown to pin the Fermi level, likely due to the unintentional formation of various sub-oxides, or even pure arsenic (As) at the interface, which may result in chemically non-abrupt interfaces. Other high dielectric constant (high-K) metal-oxide dielectrics such as hafnium oxide (HfO₂) and zirconium oxide (ZrO₂) are not likely to produce significantly better results. Even if chemically abrupt interfaces could be formed between metal-oxides and semiconductors, the different nature of metal-oxide versus semiconductor bonding can contribute to a large number of trap states at the interface. Furthermore, the extremely large polarizability of metal-oxide bonds, which gives materials like HfO₂ and ZrO₂ such large permittivity values, can also contribute to soft-optical phonon scattering, which may significantly limit carrier mobility near the semiconductor/insulator interface.

The absence of oxygen at an interface between a dielectric layer and a semiconductor can facilitate the formation of chemically abrupt, high-quality semiconductor/insulator interfaces. Further, a gate dielectric layer comprising a group III-nitride layer may provide an oxygen-free interface between the dielectric layer and a semiconductor.

In some embodiments, a semiconductor device structure includes a gate dielectric layer comprising a group III-nitride (III-N) layer. In further embodiments, a semiconductor channel layer comprises a nitride-free semiconductor layer, wherein the gate dielectric layer is disposed over the semiconductor channel layer. In some embodiments, the group-III nitride layer is disposed in contact with the nitride-free semiconductor layer.

In some embodiments, wide-bandgap III-nitride semiconductors, such as gallium nitride (GaN), aluminum nitride (AlN), and/or aluminum gallium nitride alloys (AlₓGa₁₋ₓN), are used as gate dielectric materials. In some embodiments, wide-bandgap III-nitride semiconductors are used as gate dielectric materials on Si, SiGe, Ge, and/or III-V semiconductor channel layers. In some embodiments, gate dielectric layers including AlGaN alloys can possess large bandgaps and relatively high dielectric constants. The bandgap and/or dielectric constant can be tailored based on alloy composition to attain desired device properties, such as turn-on voltage, gate leakage, etc.

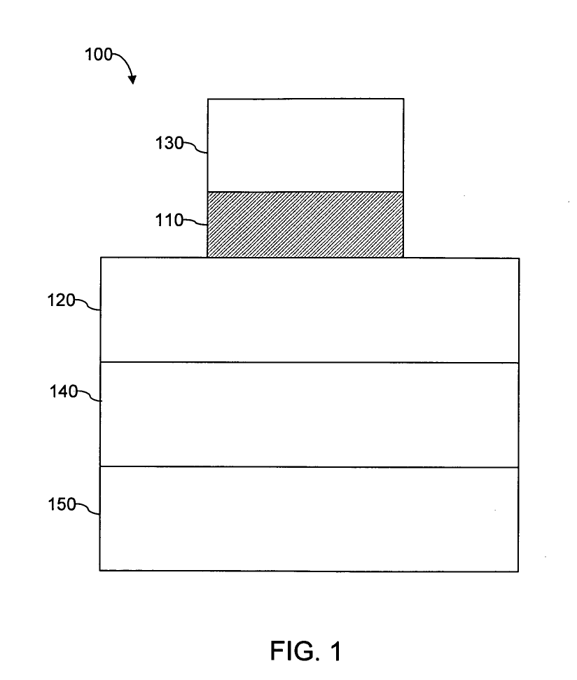

FIG. 1 is a schematic of an embodiment of a semiconductor structure 100 including a gate dielectric layer 1 10 disposed over at least a portion of a semiconductor channel layer 120. The semiconductor device structure may include a gate electrode 130 disposed over at least a portion of the gate dielectric layer 110.

Semiconductor channel layer 120 may include one or more nitride-free semiconductor layers. Semiconductor channel layer 120 may include one or more nitride-free III-V semiconductors. Examples of nitride-free group III-V semiconductors include gallium arsenide (GaAs), indium gallium arsenide (InₓGa₁₋ₓAs), gallium phosphide (GaP), indium phosphide (InP), indium gallium phosphide (InₓGa₁₋ₓP), indium arsenide (InAs), indium arsenide phosphide (InAsₓP₁₋ₓ), gallium antimonide (GaSb), indium antimonide (InSb), indium gallium antimonide (InₓGa₁₋ₓSb), and/or combinations thereof. Alternatively or additionally, semiconductor channel layer 120 may include one or more group IV semiconductors. Examples of group IV semiconductors include silicon (Si), germanium (Ge), carbon (C), silicon germanium (SiₓGe₁₋ₓ), and/or combinations thereof.

Semiconductor channel layer 120 may include one or more strained layers and/or relaxed layers. Strained layers may be tensilely and/or compressively strained. Strain in semiconductor channel layer 120 may be imparted and/or maintained by surrounding structures, including but not limited to layers disposed under and/or over semiconductor channel layer 120, as the techniques presented herein are not limited in this respect. As shall be described further, semiconductor channel layer 120 may serve as a channel layer of a semiconductor device such as a metal-insulator-semiconductor field effect transistor (MISFET).

Semiconductor channel layer 120 may be disposed over one or more intermediate layer(s) 140 which may in turn be disposed over a substrate 150. Substrate 150 may include a bulk substrate. Substrate 150 may include a silicon substrate, a gallium arsenide substrate, or a sapphire substrate. Intermediate layer(s) 140 may include one or more insulating layers, a graded buffer layer, and/or combinations thereof. In some embodiments, intermediate layer(s) between the semiconductor channel layer 120 and the substrate 150 are absent.

Intermediate layer(s) 140 may have an electrical and/or mechanical impact on the semiconductor channel layer 120. For example, when intermediate layer(s) 140 include an insulating layer, the intermediate layer(s) may create a semiconductor-on-insulator structure that may influence the electrical properties of the semiconductor device including channel layer 120. Alternatively, or additionally, intermediate layer(s) 140 may impart and/or maintain mechanical strain (e.g., tensile strain, compressive strain) in semiconductor channel layer 120. For example, when intermediate layer(s) 140 include a graded layer formed of a semiconductor structure having a graded composition (e.g., a Si₁₋ₓGeₓ, graded layer on a Si substrate, where the Si₁₋ₓGeₓ graded layer has a generally increasing germanium content in the direction normal to the substrate), the intermediate layer(s) 140 may impart strain on the semiconductor channel layer 120 (e.g., thereby forming strained silicon, strained germanium, and/or strained silicon germanium).

Gate dielectric layer 110 may be disposed over semiconductor channel layer 120. Gate dielectric layer 110 may include a group III-nitride layer. The group III-nitride layer may have a wide bandgap. As referred to herein, a wide bandgap refers to bandgaps greater than or equal to about 3 eV. In some embodiments, the group III-nitride layer may include aluminum nitride (AlN), gallium nitride (GaN), and/or aluminum gallium nitride (AlₓGa₁₋ₓN). When the group-III nitride layer of the gate dielectric layer 110 includes aluminum gallium nitride, the bandgap of the group III-nitride layer may be tailored by adjusting the ratio of various components of the alloy.

The group III-nitride layer may be amorphous, polycrystalline, and/or monocrystalline. In some embodiments, amorphous group III-nitride materials (e.g., AlₓGa₁₋ₓN) can serve as a gate dielectric layer for high-powered transistors, such as GaN transistors, due to the lack of deep-level states resulting from the lack of dislocations in the amorphous gate dielectric, which might otherwise be present for an epitaxial gate dielectric layer.

Gate electrode 130 may include any suitable electrically conducting material(s), including but not limited to a metal, such as aluminum, and/or one or more highly doped semiconductors, such as highly doped silicon or silicon germanium.

In some embodiments, the gate dielectric includes a plurality of layers. In one such embodiment, the gate dielectric layer comprises a high-K dielectric layer disposed over a group III-nitride layer.

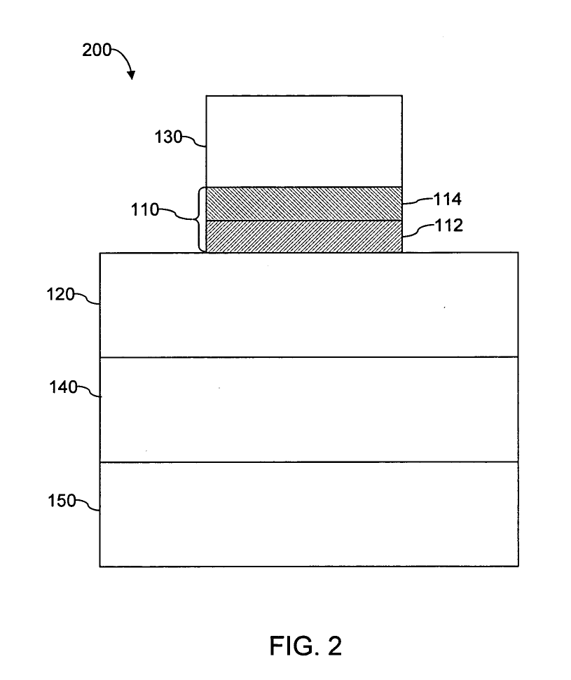

FIG. 2 illustrates such an embodiment of a semiconductor device structure 200 including a gate dielectric layer 110 that includes a high-K dielectric layer 114 disposed over a group III-nitride layer 112. High-K dielectric layer 114 may include a material other than the group III-nitride layer 112. In one embodiment, high-K dielectric layer 114 includes hafnium oxide (HfO₂). In one embodiment, high-K dielectric layer 114 includes zirconium oxide (ZrO₂). In one embodiment, high-K dielectric layer 114 includes aluminum oxide (Al₂O₃). In one embodiment, high-K dielectric layer 114 includes a zirconium silicate and/or oxides of zirconium silicate. In some embodiments, high-K dielectric layer 114 includes a group IV-nitride, such as silicon nitride. Those of skill in the art would appreciate the range of dielectric constants that fall under the classification of a high-K dielectric. In some embodiments, a high-K dielectric has a dielectric constant greater than about 10. In some embodiments, a high-K dielectric has a dielectric constant greater than about 10 and less than about 50. This should be contrasted with the dielectric constant of silicon dioxide which is about 3.9.

Disposing a high-K dielectric over group-III nitride layer 112 avoids disposing the high-K dielectric on the semiconductor channel layer. As previously described, disposing such high-K metal-oxide dielectrics on semiconductors may result in chemically non-abrupt interfaces and/or a large number of trap states at the interface. Furthermore, the extremely large polarizability of metal-oxide bonds can also result in significant soft-optical phonon scattering, which may significantly limit carrier mobility near the semiconductor/insulator interface. Disposing group-III nitride layer 112 between high-K dielectric layer 114 and the semiconductor channel layer 120 can avoid the above-mentioned problems while still contributing to a high dielectric constant for the gate dielectric layer 110.

In some embodiments, the gate dielectric layer comprises a layer including a nitride compound of a nitride-free semiconductor. In some such embodiments, the nitride-free semiconductor may include one or more semiconductor materials of the semiconductor channel layer.

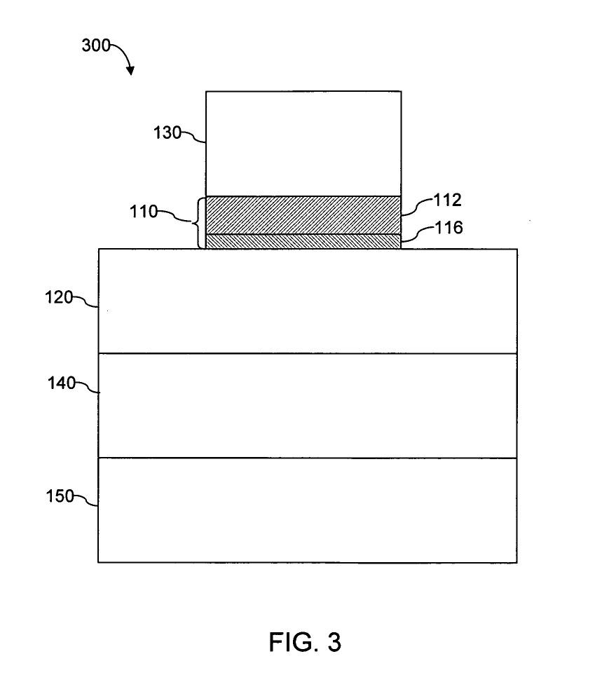

FIG. 3 illustrates such an embodiment of a semiconductor device structure 300 including a gate dielectric layer 110 that includes a group III-nitride layer 112 disposed over a nitride compound 116 of a nitride-free semiconductor. The nitride compound 116 of the nitride-free semiconductor is thus disposed between the semiconductor channel layer 120 and the group-III nitride layer 112.

In some embodiments, the layer including the nitride compound 116 of a nitride-free semiconductor is disposed in contact with the semiconductor channel layer 120. The nitride compound 116 of the nitride-free semiconductor may be a nitride compound of a nitride-free semiconductor of the channel layer 120. Such a structure may be formed, for example, via the nitridation of an exposed surface of the semiconductor channel layer 120. The nitridation may be performed during the deposition of the gate dielectric and/or channel layer, as described further below.

As should be appreciated, a gate dielectric may include both a high-K dielectric disposed over a group III-nitride layer and a nitride compound of a nitride-free semiconductor disposed under the group III-nitride layer.

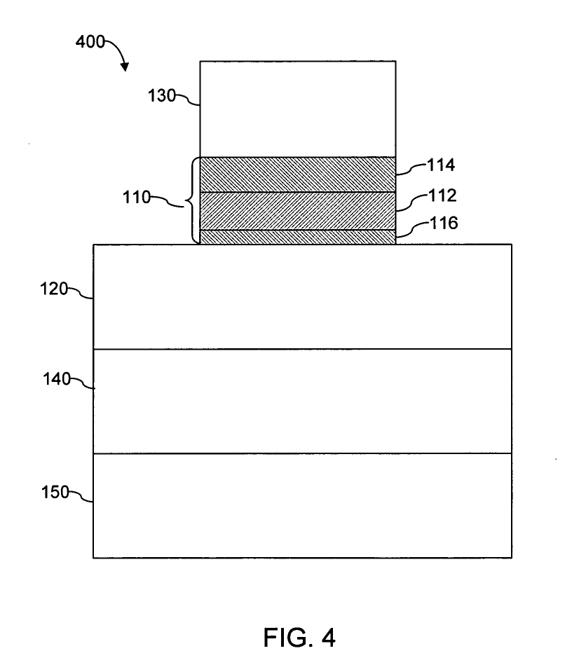

FIG. 4 illustrates such an embodiment of a semiconductor device structure 400 including a gate dielectric layer 110 including a group-III nitride layer 112, a high-K dielectric layer 114, and a nitride compound 116 of the nitride-free semiconductor. Group III-nitride layer 112 may be disposed over a nitride compound 116 of a nitride-free semiconductor, as described for structure 300. High-K dielectric layer 114 may be disposed over the group III-nitride layer 112, as described for structure 200. However, it should be appreciated that the gate dielectric of a device structure may include some or all of the aforementioned layers, and my also include other layers of materials, as the techniques presented herein are not limited in this respect.

Device structures including gate dielectric layers may include MISFETs, where N-type and P-type MISFETs may be used in complementary MISFET circuits.

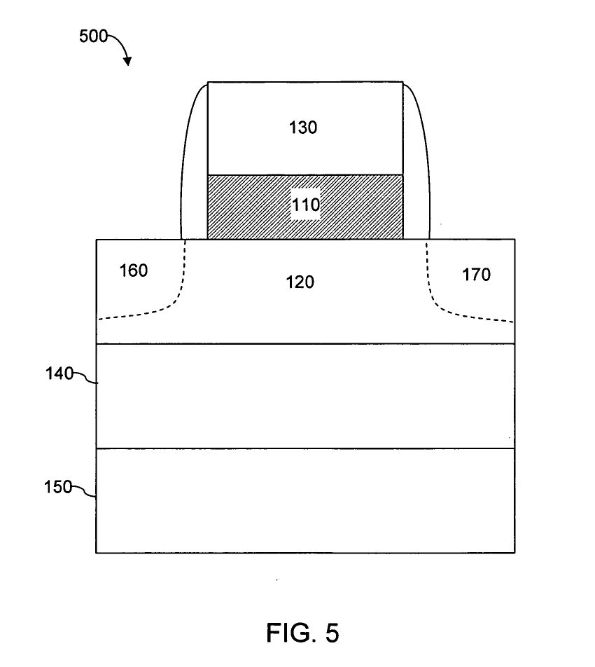

FIG. 5 illustrates a cross-section of a MISFET device 500 including a gate dielectric layer 110. Gate dielectric layer 110 can include one or more of the layers described herein. For example gate dielectric layer 110 may include layers such as those described for the gate dielectric layers of structures 200, 300, or 400. Alternatively, or additionally, gate dielectric layer 110 may include other suitable layers. MISFET device 500 further can include a source region 160 and a drain region 170 doped with a first type of dopant (e.g., n or p doping). Semiconductor channel layer 120 may be doped with a second type of dopant (e.g., p or n doping). Alternatively or additionally, semiconductor channel layer 120 may include modulation doping, wherein a highly doped plane (not shown) is present in the channel layer 120. Semiconductor channel layer 120 may include one or more semiconductor layers. As previously described, semiconductor channel layer 120 may include strained layers (e.g., tensilely and/or compressively strained layers) and/or relaxed layers. Semiconductor channel layer 120 may be disposed over one or more intermediate layer(s) 140 which may in turn be disposed over a substrate 150.

N-type MISFET devices may be formed which have n-type doped source and drain regions, and wherein the application of a suitable voltage to gate electrode 130 forms an n-type channel region in semiconductor channel layer 120. P-type MISFET devices may be formed which have p-type doped source and drain regions, and wherein the application of a suitable voltage to gate electrode 130 forms a p-type channel region in semiconductor channel layer 120. N-type and P-type MISFETs may possess low leakage currents via the use of gate dielectrics having a wide bandgap. Such complementary MISFETs may be used to form complementary MISFET circuits having low power consumption, similar to silicon CMOS circuits having silicon channels and silicon dioxide gate dielectrics layers.

The gate dielectric layers presented herein and device structures including the gate dielectric layers may be formed via deposition techniques. Alternatively, or additionally, wafer bonding may be used to form the gate dielectric layers on semiconductor channel layers.

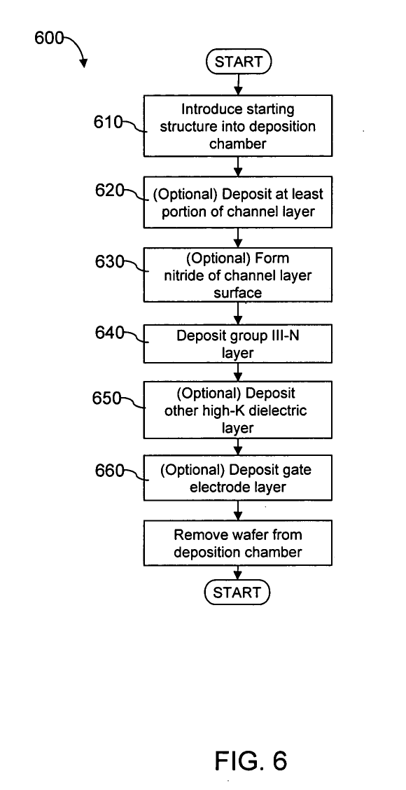

FIG. 6 is a flowchart 600 of a method of forming a structure including a gate dielectric using deposition process(es). In one embodiment, a gate dielectric layer and at least a portion of a channel layer are deposited using the same deposition chamber, for example, without removing the structure from the chamber in between the deposition of the gate dielectric layer and the channel layer. In another embodiment, a gate electrode layer is deposited using the same deposition chamber as for the gate dielectric layer. As used herein, a combined deposition process refers to deposition processes for two or more layers where there is no substantial atmospheric exposure between the deposition of each layer. In a preferred embodiment, a combined deposition process involves the deposition of two or more layers in one deposition chamber.

The method may include providing a starting structure (e.g., a wafer) on which layers may be deposited. The starting structure may include a substrate which may have one or more intermediate layers disposed thereon, for example, substrate 150 which may have intermediate layer(s) 140 disposed thereon as shown for structure 100. The starting structure may include a portion or all of channel layer 120 which may be disposed over intermediate layer(s) 140, or directly over substrate 150 when no intermediate layer(s) are present. Alternatively, the starting structure may not include any of the channel layer 120.

The method may include introducing the starting structure into a deposition reactor (act 610). The deposition chamber may be a chemical vapor deposition (CVD) reactor, such as a low-pressure chemical vapor deposition (LPCVD) reactor. Prior to introduction into the deposition reactor, Si and Ge surfaces (e.g., of a starting structure) can be prepared for deposition by etching in solutions of about 3:1 H₂SO₄:H₂O₂ or H₂0₂ respectively, followed by a dip in dilute HF to leave the surface H-terminated. GaAs and InGaAs surfaces (e.g., of a starting structure) can be prepared for deposition by first stripping the native oxide using diluted HCl followed by etching in about 10:1:1 H₂SO₄:H2O:H₂O₂.

In some embodiments, amorphous, polycrystalline, and/or epitaxial gate dielectric III-N alloys (e.g., AlN, GaN, AlGaN) can be grown in the same deposition reactor used for SiGe, III-As, III-P, and/or III-Sb channel layer materials. Therefore, the channel layer, gate dielectric layer, and optionally also the gate electrode layer (e.g., Al, heavily-doped poly-Si, poly-Ge, and/or poly-SiGe) can be deposited in situ without exposure to oxygen or steam. In other embodiments, one or more of the channel layer, gate dielectric layer, and/or gate electrode layer are deposited using different deposition chambers (e.g., reactors, sputtering chambers, evaporation chambers).

In some embodiments, dimethylhydrazine (DMHy) can be used as a nitrogen source for a reactor used to deposit the channel layer, gate dielectric layer, and/or the gate electrode layer. In some embodiments, films can be grown in a commercial LPCVD system using SiH₄, GeH₄, and AsH₃ hydride sources and trimethylgallium (TMGa), trimethylaluminum (TMAl), and dimethylhydrazine (DMHy) metalorganic (MO) sources.

The method may include depositing all or at least a portion of a channel layer (act 620) on the starting structure. In some embodiments, this deposition is omitted as the starting structure includes the entire channel layer. Otherwise, at least a portion or all of the channel layer may be deposited. The deposition of the channel layer may include heteroepitaxial and/or homoepitaxial deposition. In homoepitaxy, the deposited material is the same as that of the starting surface. Such a process may be advantageous in burying any impurities (e.g., carbon) present at the starting surface. Alternatively, or additionally, in heteroepitaxy, the deposited material may have a different composition that that of the starting surface. Heteroepitaxial deposition allows for the formation of channel layer including heterostructures. For example, one or more quantum wells may be deposited.

Optionally, the method may include forming a nitrided layer of the channel layer semiconductor (act 630). Such a process may be accomplished by introducing (e.g., flowing) a nitrogen source gas into the deposition reactor. In one embodiment, the surface of the channel layer may be exposed to DMHy to form a thin, nitrided layer of the channel layer surface. Since the surface of the channel layer may be a nitride-free semiconductor, the compound that forms as a result of introducing the nitrogen source gas may be a nitride compound of the nitride-free semiconductor. Such a layer may serve as part of the dielectric gate layer. Alternatively or additionally, one or more source gases may be introduced into the deposition chamber in addition to the nitrogen source so as to deposit any other desired nitride compound. For example, silane (SiH₄) and/or (GeH₄) may be flowed with a nitrogen source, such as DMHy, to deposit an interfacial (Si₁₋ₓGeₓ)₃N₄ layer.

The method may include depositing a group III-nitride layer (act 640). In some embodiments, one or more group III-nitride materials, such as AlN, GaN, and/or AlₓGa₁₋ₓN layers, may be deposited to form at least part of the group III-nitride layer. AlN layers can be grown at a temperature of about 550° C. using TMAl and DMHy as source gases (V/III molar ratio=50) and high-purity nitrogen as the carrier gas with a reactor pressure of about 100 Torr. AlN layers can be grown at 550° C., at a reactor pressure of 100 Torr, using source gas flow rates of about 400 sccm DMHy and about 40 sccm TMAl (V/III ratio=50). GaN layers can be grown using TMGa and DMHy as source gases. AlₓGa₁₋ₓN layers can be grown by using TMAl, TMGa, and DMHy as source gases, where the flow rate ratios may be selected to deposit a desired composition of AlₓGa₁₋ₓN. Such a process enables the bandgap of the dielectric gate layer to be tailored according to desired device properties.

AlN, GaN, and/or AlₓGa₁₋ₓN layers can be grown in a reactor that may rotate the wafers so as to ensure uniform deposition across an entire wafer and between different wafers in a deposition lot. In such reactors, the wafer rotation speed can be about 100 rpm, and the carrier gas can be N₂ and/or H₂. Deposition temperature can be used to control the degree of crystallinity and to control the impurity concentration in the deposited layers, as should be appreciated by those of skill in the art.

Optionally, the method may include depositing a high-K dielectric layer over the group III-nitride layer (act 650). The high-K dielectric material, such as HfO₂, ZrO₂, and/or Al₂O₃, may be deposited over the group III-nitride layer, which may include AlN, GaN, and/or AlₓGa₁₋ₓN. The group III-nitride layer can facilitate the formation of a high-quality interface between the semiconductor channel layer and the gate dielectric layer, while the high-K dielectric material(s) disposed over (e.g., in contact with) the group-III nitride layer may increase the effective dielectric constant of the combined gate dielectric layer.

The method may include depositing a gate electrode layer (act 660). In some embodiments, the gate electrode layer (e.g., metal and/or highly doped semiconductor) can be deposited in situ, to form an entire device structure (e.g., a metal-insulator-semiconductor structure) in a single deposition process. For example, heavily-doped Si, SiₓGe₁₋ₓ, Ge, and/or Al pyrolyzed from TMAl could serve as the gate electrode layer. The ability to deposit entire gate stacks in situ can simplify MISFET fabrication by reducing the number of process steps, ultimately leading to higher-throughput and lower-cost processing of MISFET devices. Alternatively or additionally, a gate electrode layer can be deposited (e.g., sputtered) onto the wafers ex situ following the gate dielectric layer deposition.

The wafer may then be removed from the deposition reactor (act 670) and any further device processing may be performed. Further processing may include patterning gate regions (e.g., using photolithography processes), implantation to form source and drain regions, interconnect formation and other related processing used to form desired devices (e.g., MISFETs and complementary MISFET circuits).

### WORKING EXAMPLES

Various working examples are presented. Such examples are not meant to be limiting as the techniques presented are not restricted to only the use of the materials and/or structures of the working examples.

Semiconductor device structures including gate dielectric layers were deposited using various deposition processes, referred to herein as processes A, B, C, and D. In a baseline process A, no other deposition processes were performed prior to the deposition of a group III-nitride, which in these working examples was AlN, and an Al gate electrode layer. In process B, DMHy was flowed over the surface of a channel layer for about 5 minutes to form a thin, nitrided layer at the surface prior to flowing TMAl to form the AlN layer. In process C, a homoepitaxial film having the same composition as the channel layer surface was grown prior to the growth of the AlN gate dielectric layer. In process D, following homoepitaxy and prior to the deposition of the AlN layer, the surface of the channel layer was exposed to DMHy for about 5 minutes to form a thin, nitrided layer at the surface.

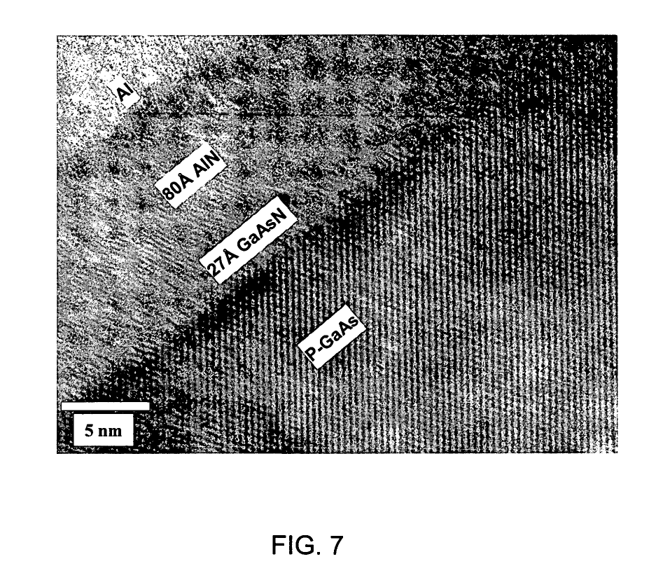

FIG. 7 is a cross-sectional transmission electron microscopy (TEM) image of a structure resulting from performing process D using a p-type GaAs starting wafer. The structure was formed by first performing GaAs homoepitaxy at a growth temperature of about 650° C., with a reactor pressure of 100 Torr, flow rates of 50 sccm TMGa and 200 sccm AsH₃, and a wafer rotation speed of about 100 rpm. Then, the surface of the GaAs channel layer was exposed to DMHy for about 5 minutes to form a thin, nitrided layer (GaAsN) at the surface. Next, an AlN layer was deposited using TMAl, and then the Al layer was pyrolyzed from TMAl.

Capacitors were fabricated to measure the electrical properties of the deposited gate dielectric structures. Capacitor electrical properties were measured using an HP 4294A high-frequency capacitance-voltage (HFCV) meter. Devices were measured in ambient light at room temperature. All measurement results presented herein are for frequencies of 1 MHz.

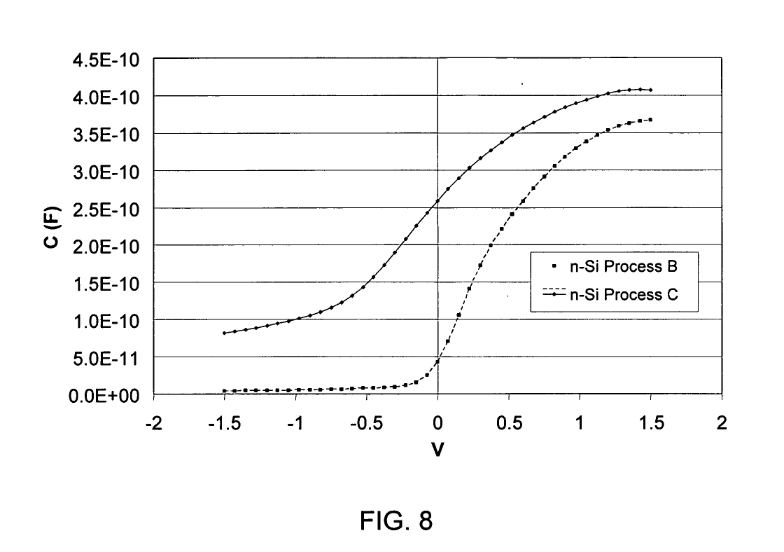

FIG. 8 is a chart of measured HFCV characteristics for Al/AlN/n-Si capacitors. The capacitance measurements indicate that AlN films deposited onto Si result in excellent high-frequency capacitance-voltage (CV) characteristics. These capacitors also exhibit very little frequency dispersion and hysteresis. Such capacitors on Si were found to produce clean accumulation and depletion regardless of pre-treatment steps, possibly due to the formation of Si₃N₄ on the Si surface.

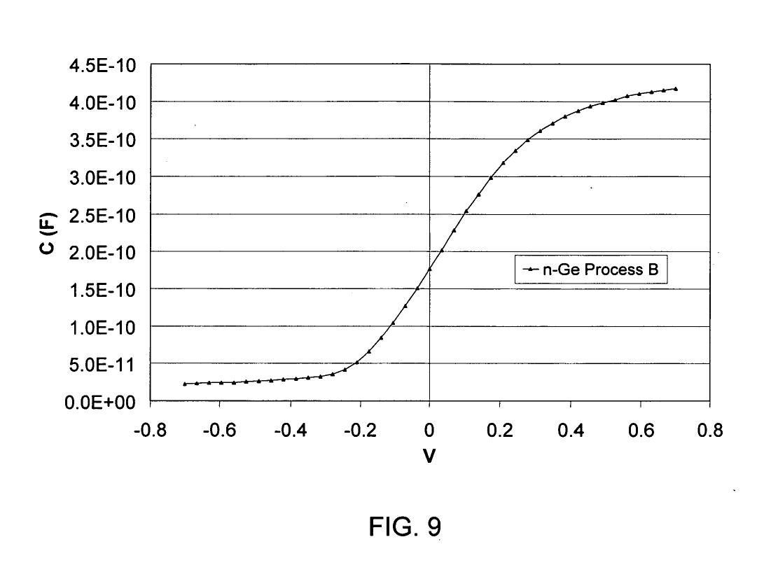

FIG. 9 is a chart of measured HFCV characteristics for Al/AlN/n-Ge capacitors. Pre-nitridation (process B) utilizing DMHy as the nitrogen source was found to produce excellent capacitor characteristics on Ge.

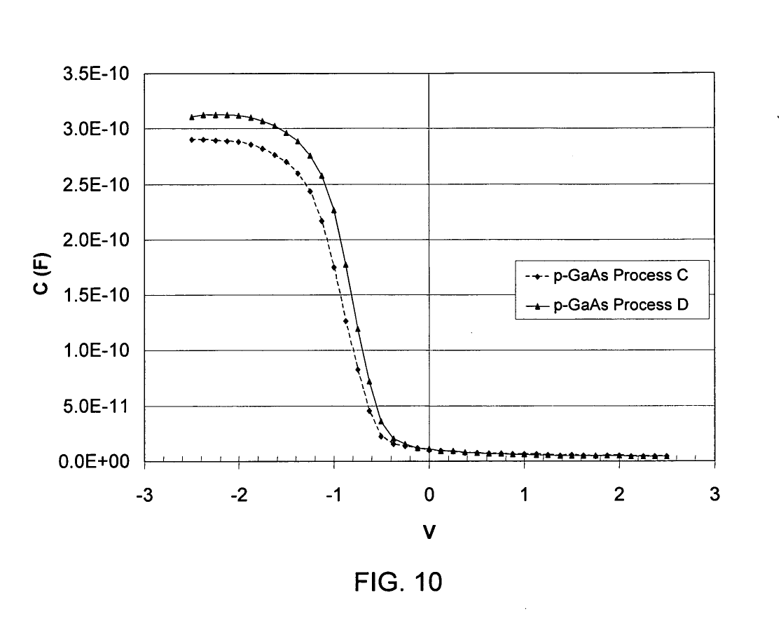

FIG. 10 is a chart of measured HFCV characteristics for Al/AlN/p-GaAs capacitors. GaAs capacitors prepared by processes C and D exhibited similar high-frequency C-V characteristics.

Although the working examples shown used gate dielectric layers that included AlN, the techniques presented are not limited in this respect. More generally, the gate dielectric layer can include one or more III-N semiconductors, such as wide bandgap III-N semiconductors. Furthermore, although the examples presented used Si, Ge, and GaAs channels, wide bandgap alloys can serve as dielectrics for high-mobility Ill-V semiconductor channels including, but not limited to, GaP, InGaP, InGaAs, InP, InAsP, InAs, GaSb, InGaSb, and InSb.

Methods described herein can be used to form gate dielectrics layers that can exhibit desirable high-frequency C-V (HFCV) characteristics (e.g., on Si, Ge, and/or GaAs channels). Capacitor structures described herein can be building blocks in the fabrication of high-speed and/or low-power MISFETs having Ge and/or III-V channels. The ability to deposit entire MIS stacks in situ can facilitate interface control and simplified processing.

This invention is not limited in its application to the details of construction and the arrangement of components set forth in the following description or illustrated in the drawings. The invention is capable of other embodiments and of being practiced or of being carried out in various ways. Also, the phraseology and terminology used herein is for the purpose of description and should not be regarded as limiting. The use of “including,” “comprising,” or “having,” “containing,” “involving,” and variations thereof herein, is meant to encompass the items listed thereafter and equivalents thereof as well as additional items.

Having thus described several aspects of at least one embodiment of this invention, it is to be appreciated various alterations, modifications, and improvements will readily occur to those skilled in the art. Such alterations, modifications, and improvements are intended to be part of this disclosure, and are intended to be within the spirit and scope of the invention. Accordingly, the foregoing description and drawings are by way of example only.

What is claimed is:

1. A semiconductor structure comprising:
a semiconductor channel layer comprising a nitride-free semiconductor layer; and
a gate dielectric layer comprising a group III-nitride layer, wherein the gate dielectric layer is disposed over the semiconductor channel layer.

2. The structure of claim 1, wherein the group-III nitride layer is disposed in contact with the nitride-free semiconductor layer.

3. The structure of claim 1, wherein the gate dielectric layer further comprises a layer including a nitride compound of the nitride-free semiconductor.

4. The structure of claim 3, wherein the layer including the nitride compound of the nitride-free semiconductor is disposed between the nitride-free semiconductor layer and the group-III nitride layer.

5. The structure of claim 4, wherein the layer including the nitride compound of the nitride-free semiconductor is disposed in contact with the nitride-free semiconductor layer.

6. The structure of claim 1, wherein the gate dielectric layer further comprises a high-K dielectric layer disposed over the group III-nitride layer.

7. The structure of claim 6, wherein the high-K dielectric layer comprises hafnium oxide.

8. The structure of claim 6, wherein the high-K dielectric layer comprises zirconium oxide.

9. The structure of claim 6, wherein the high-K dielectric layer comprises aluminum oxide.

10. The structure of claim 6, wherein the high-K dielectric layer comprises a group IV-nitride.

11. The structure of claim 10, wherein the group IV-nitride comprises silicon nitride.

12. The structure of claim 1, wherein the group III-nitride layer is amorphous.

13. The structure of claim 1, wherein the group III-nitride layer is polycrystalline.

14. The structure of claim 1, wherein the group III-nitride layer is monocrystalline.

15. The structure of claim 1, wherein the group III-nitride layer has a wide bandgap.

16. The structure of claim 1, wherein the group III-nitride layer comprises aluminum nitride.

17. The structure of claim 1, wherein the group III-nitride layer comprises gallium nitride.

18. The structure of claim 1, wherein the group III-nitride layer comprises aluminum gallium nitride.

19. The structure of claim 1, wherein the nitride-free semiconductor layer comprises a III-V semiconductor.

20. The structure of claim 19, wherein the III-V semiconductor comprises gallium arsenide.

21. The structure of claim 19, wherein the III-V semiconductor comprises indium gallium arsenide.

22. The structure of claim 1, wherein the nitride-free semiconductor layer comprises a group IV semiconductor.

23. The structure of claim 1, further comprising:
a gate electrode layer disposed over the gate dielectric layer.

24. The structure of claim 23, wherein the gate electrode layer comprises aluminum.

25. The structure of claim 23, wherein the gate electrode layer comprises a highly doped semiconductor.

26. A method of making a semiconductor structure, the method comprising:
(A) providing a semiconductor channel layer comprising a nitride-free semiconductor layer; and
(B) providing a gate dielectric layer comprising a group III-nitride layer, wherein the gate dielectric layer is disposed over the semiconductor channel layer.

27. The method of claim 26, wherein act (A) comprises depositing at least part of the semiconductor channel layer comprising the nitride-free semiconductor layer.

28. The method of claim 26, wherein act (B) comprises depositing the gate dielectric layer comprising the group III-nitride layer.

29. The method of claim 26, wherein act (A) comprises depositing at least part of the semiconductor channel layer comprising the nitride-free semiconductor layer and (B) comprises depositing the gate dielectric layer comprising the group III-nitride layer, and wherein acts (A) and (B) are performed in one combined deposition process.

30. The method of claim 29, further comprising (C) depositing a gate electrode layer over the gate dielectric layer, and wherein acts (A) and (B) and (C) are performed in one combined deposition process.

31. The method of claim 26, wherein the group III-nitride layer comprises at least one of aluminum nitride, gallium nitride, and aluminum gallium nitride.

32. The method of claim 26, wherein the nitride-free semiconductor layer comprises a III-V semiconductor.

33. The method of claim 26, wherein the gate dielectric layer further comprises a high-K dielectric layer disposed over the group III-nitride layer.

34. The method of claim 26, wherein act (B) further comprises performing nitridation of at least part of the nitride-free semiconductor layer.

35. A metal-insulator-semiconductor field effect transistor (MISFIT) device structure comprising:
a semiconductor channel layer comprising a nitride-free semiconductor layer;
a gate dielectric layer comprising a group III-nitride layer, wherein the gate dielectric layer is disposed over the semiconductor channel layer;
a gate electrode disposed over the gate dielectric; and
a source region and a drain region separated by the semiconductor channel layer.

36. The device of claim 35, wherein the gate dielectric layer further comprises a layer including a nitride compound of the nitride-free semiconductor.

37. The device of claim 35, wherein the gate dielectric layer further comprises a high-K dielectric layer disposed over the group III-nitride layer.
